(19) United States
(12) Patent Application Publication
(10) Pub. No.: US 2026/0016752 A1
(43) Pub. Date: Jan. 15, 2026

(54) THICKENING COMPOSITION, METHOD FOR MANUFACTURING THICKENED RESIST PATTERN, AND METHOD FOR MANUFACTURING PROCESSED SUBSTRATE

(71) Applicant: Merck Patent GmbH, Darmstadt (DE)

(72) Inventors: Hiroshi Yanagita, Shizuoka (JP); Kazuma Yamamoto, Shizuoka (JP)

(21) Appl. No.: 19/334,697

(22) Filed: Sep. 19, 2025

Related U.S. Application Data
(63) Continuation of application No. PCT/EP2024/057099, filed on Mar. 18, 2024.

(30) Foreign Application Priority Data
Mar. 20, 2023 (JP) 2023-044684

(51) Int. Cl. G03F 7/105; C08F 116/16; C08F 116/20; G03F 7/00; G03F 7/16; H01L 21/027

(52) U.S. Cl. CPC G03F 7/105; C08F 116/16; C08F 116/20; G03F 7/168; G03F 7/70033; H01L 21/0274

(57) ABSTRACT

A thickening composition includes a polymer (A) comprising a repeating unit (A1) represented by the formula (a1) and a solvent (B), all of which are defined herein.

### CROSS-REFERENCE TO RELATED APPLICATIONS

This application is a Continuation under 35 USC § 111(a) of International Patent Application No. PCT/EP2024/057099 filed Mar. 18, 2024 which claims priority to the Japanese Patent Application number 2023-044684, filed Mar. 20, 2023. The contents of these applications are incorporated herein by reference in their entirety.

### BACKGROUND OF THE INVENTION

### Technical Field

The present invention relates to a thickening composition, a method for manufacturing a thickened resist pattern, and a method for manufacturing a processed substrate.

### Background Art

In recent years there is an increasing need for high integration of LSI, and in turn a finer resist pattern is required. In order to respond such needs, lithography processes using KrF excimer laser, ArF excimer laser, extreme ultraviolet ray, X-ray of short wavelength, electron beam or the like have been put into practice.

In order to obtain a finer pattern, there is a known method in which a resist pattern that is stably obtained by a conventional method is covered with a composition comprising a polymer to thicken the resist pattern and the hole diameter or separation width are made finer as disclosed in JP2014-170190 A. This mainly aims to thicken the width of the resist pattern, and the composition comprising a polymer may be further applied after developing the resist pattern once.

Also, while a thicker resist pattern having a high aspect ratio is required, a composition comprising a vinyl resin and an amine compound has also been developed as disclosed in JP2017-165846 A.

Further, a technique for manufacturing a thickened resist pattern using a solution comprising a polymer and a solvent has been studied as disclosed in JP2022-096214 A.

### SUMMARY OF THE INVENTION

### Problems to be Solved by the Invention

The inventors noticed that in EUV exposure, which is expected to be a high-definition technology, when used as an etching mask, it may not be able to sufficiently show its durability as a mask, and the object to be masked may be etched away at the end of the etching process.

The present inventors have considered that there are one or more problems still needing improvements in the method for manufacturing a resist pattern. These include, for example, the following: thickening a fine resist pattern; obtaining a fine resist pattern useful as an etching mask; suppressing the resist from dissolving after applying the thickening composition on the resist; the exposed part of the thickening layer can be sufficiently dissolved in the developer; obtaining a resist pattern with sufficient etching resistance; obtaining sufficient resolution even using an exposure machine with an increased numerical aperture; obtaining fine patterns with suppressed pattern width variations; obtaining a resist pattern with a high aspect ratio; widening the process window; and improving the manufacturing yield.

### Means for Solving the Problems

A thickening composition according to the present invention comprises:
a polymer (A) comprising a repeating unit (A1) represented by the formula (a1) and a solvent (B):

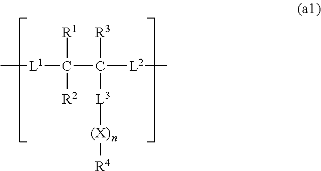

wherein
   i. L¹, L² and L³ are each independently a single bond, C₁₋₁₀ linear alkylene, C₃₋₁₀ branched alkylene or C₃₋₁₀ cyclic alkylene;
   ii. R¹, R² and R³ are each independently H, C₁₋₁₀ linear alkyl, C₃₋₁₀ branched alkyl, C₃₋₁₀ cyclic alkyl, C₆₋₁₅ aryl or C₆₋₁₅ aralkyl;
   iii. R⁴ is C₁₋₁₅ linear alkyl, C₃₋₁₅ branched alkyl, C₃₋₁₅ cyclic alkyl, C₆₋₁₅ aryl, C₆₋₁₅ aralkyl or a combination of any of these;
   iv. wherein at least one of hydrogen atoms in R⁴ can be replaced with C₁₋₅ linear alkyl —COOH or —OH;
   v. wherein at least one of non-adjacent methylene (—CH₂—) in L¹, L², L³, R¹, R², R³ and R⁴ can be replaced with —O—, —S—, —CO—, —CO—O—, —O—CO—, —O—CO—O—, -CR⁵═CR⁶- or —C≡C—;
   vi. R⁵ and R⁶ are each independently H or C₁₋₆ linear alkyl;
   vii. X is O or S; and
   viii. n is 0 or 1.

A method for manufacturing a thickened resist pattern according to the present invention comprises the following steps:
(1) applying a resist composition above a substrate to form a resist layer from the resist composition;
(2a) exposing the resist layer;
(2b) applying the above-described thickening composition to the resist layer to form a thickening layer; and
(2c) developing the resist layer and the thickening layer.

A method for manufacturing a processed substrate comprises the following steps:
forming the above-described thickened resist pattern; and
(3) processing using the thickened resist pattern as a mask.

A method for manufacturing a device comprises the above-described method for manufacturing a processed substrate.

The present invention relates to the use of a composition comprising a polymer (A) comprising a repeating unit (a1) represented by the formula (a1), and a solvent (B) for forming a film on a resist layer. The structure of the polymer (A) is as described above.

### Effects of the Invention

According to the present invention, one or more of the following effects can be desired: thickening a fine resist pattern; obtaining a fine resist pattern useful as an etching mask; suppressing the resist from dissolving after applying the thickening composition on the resist; the exposed part of the thickening layer can be sufficiently dissolved in the developer; obtaining a resist pattern with sufficient etching resistance; obtaining sufficient resolution even using an exposure machine with an increased numerical aperture; obtaining fine patterns with suppressed pattern width variations; obtaining a resist pattern with a high aspect ratio; widening the process window; and improving the manufacturing yield.

### BRIEF DESCRIPTION OF THE DRAWINGS

FIG. 1 is a schematic illustration showing one embodiment of a method for manufacturing a thickened resist pattern.

### DETAILED DESCRIPTION OF THE INVENTION

### MODE FOR CARRYING OUT THE INVENTION

### Definitions

Unless otherwise specified in the present specification, the definitions and examples described in this paragraph are as follows.

The singular form includes the plural form and “one” or “that” means “at least one”. An element of a concept can be expressed by a plurality of species, and when the amount (for example, mass % or mol %) is described, it means sum of the plurality of species.

“And/or” includes a combination of all elements and also includes single use of the element.

When a numerical range is indicated using “to” or “-”, it includes both endpoints and units thereof are common. For example, 5 to 25 mol % means 5 mol % or more and 25 mol % or less.

The descriptions such as “C_{x-y}”, “Cₓ-C_{y}” and “Cₓ” mean the number of carbons in a molecule or substituent. For example, C₁₋₆ alkyl means an alkyl chain having 1 or more and 6 or less carbons (methyl, ethyl, propyl, butyl, pentyl, hexyl etc.).

When a polymer has a plural types of repeating units, these repeating units copolymerize. This copolymerization may be any of alternating copolymerization, random copolymerization, block copolymerization, graft copolymerization, or a mixture thereof. When a polymer or resin is represented by a structural formula, n, m or the like that is attached next to parentheses indicate the number of repetitions.

Celsius is used as the temperature unit. For example, 20 degrees means 20 degrees Celsius.

The additive refers to a compound itself having a function thereof (for example, in the case of a base generator, a compound itself that generates a base). An embodiment in which the compound is dissolved or dispersed in a solvent and added to a composition is also possible. As one embodiment of the present invention, it is preferable that such a solvent is contained in the composition according to the present invention as the solvent (B) or another component.

Aryl refers to a group containing one or more aromatic rings and includes phenyl, anthracenyl, naphthyl, phenanthrenyl, fluorenyl, pyrenyl and the like, but is not limited to these.

Aralkyl refers to alkyl substituted with aryl and includes benzyl and phenylethyl and the like but is not limited to these.

Hereinafter, embodiments of the present invention are described in detail.

### Thickening Composition

The thickening composition according to the present invention comprises a polymer (A) comprising a repeating unit (a1) represented by the formula (a1) and a solvent (B).

The thickening composition according to the present invention may be applied on a resist layer before development or may be applied on a resist layer after development.

In a preferred embodiment, the film thickening composition according to the present invention is applied on a resist layer of before the development and is not applied between resist patterns of after the development. However, “development” within the expression of “after the development” does not include the development when the already removed resist layer has been patterned. For example, in the case of a design in which resist patterning is performed a plurality of times in succession, it is possible to use the thickening composition of the present invention to thicken the resist layer in the subsequent process even after the resist has been developed in the previous process.

### (A) Polymer

The polymer (A) used in the present invention comprises a repeating unit (A1) represented by the formula (a1).

One of the characteristics of the thickening composition according to the present invention is that it comprises a polymer (A) comprising a repeating unit (A1), and it can be thought that this makes it possible to achieve a thicker film.

The repeating unit (A1) represented by the formula (a1) is as follows:

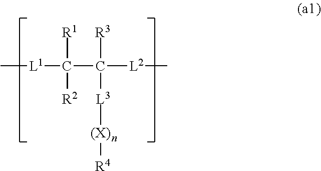

wherein
L¹, L² and L³ are each independently a single bond, C₁₋₁₀ linear alkylene, C₃₋₁₀ branched alkylene or C₃₋₁₀ cyclic alkylene (preferably a single bond or methyl; more preferably a single bond).

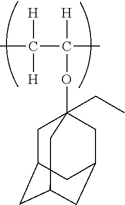

The following compound can also be read by the formula (a1). L¹, L² and L³ are single bonds, R¹, R² and R³ are H, X is O, R⁴ is a combination of C₁ linear alkyl, C₆ cyclic alkyl and C₁ linear alkyl in which one hydrogen atom is replaced with —OH, and n is 1. As this example shows, when R⁴ is a combination of a plurality of substituents, a monovalent substituent can be regarded as a divalent substitute, which is obtained by removing one hydrogen atom from the monovalent substituent and may be combined with other substituent(s).

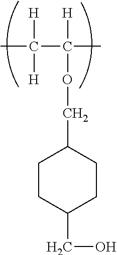

R⁴ can be represented also by the formula (a2)

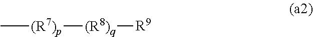

wherein
R⁷ is C₁₋₁₅ linear alkylene, C₃₋₁₅ branched alkylene, C₃₋₁₅ cyclic alkylene or phenylene,
R⁸ is C₁₋₁₅ linear alkylene, C₃₋₁₅ branched alkylene, C₃₋₁₅ cyclic alkylene or phenylene,
R⁹ is C₁₋₁₅ linear alkyl, C₃₋₁₅ branched alkyl, C₃₋₁₅ cyclic alkyl, phenyl or benzyl, where one or more hydrogen in any of R⁷, R⁸ or R⁹ can be replaced with C₁₋₅ linear alkyl, —COOH or —OH, and
p and q are each independently 0 or 1.

When R⁷, R⁸ or R⁹ is C₁₋₁₅ linear alkyl, and one or more hydrogen of the linear alkyl are replaced with C₁₋₅ linear alkyl, R⁷, R⁸ or R⁹ can be branched alkyl.

In one preferred embodiment, p and q are 0, R⁹ is C₁₋₁₅ linear alkyl, C₃₋₁₅ branched alkyl, C₃₋₁₅ cyclic alkyl, phenyl or benzyl, and one or more hydrogen of R⁹ are replaced with C₁₋₅ linear alkyl, —COOH or —OH. More preferably, p and q are 0, R⁹ is C₁₋₁₀ linear alkyl, C₃₋₁₀ branched alkyl, C₃₋₁₀ cyclic alkyl, phenyl or benzyl, and one or more hydrogen of R⁹ can be replaced with C₁₋₅ linear alkyl, —COOH or —OH. Further, p and q are 0, R⁹ is C₁₋₈ linear alkyl, C₃₋₈ branched alkyl, C₃₋₁₀ cyclic alkyl, phenyl or benzyl, and one or more hydrogen of R⁹ can be replaced with OH.

In one preferred embodiment, p and q are 1, R⁷ is C₁₋₁₀ linear alkylene, R⁸ is C₃₋₁₀ cyclic alkylene, R⁹ is C₃₋₁₀ linear alkyl, and one or more hydrogen of R⁹ can be replaced with —OH.

Examples of R⁴ include n-propyl, n-butyl, isopropyl, isobutyl, cycloalkyl, 2-ethylhexyl, hydroxyethyl, hydroxypropyl, hydroxybutyl, 4-(hydroxymethyl)cyclohexylmethyl, adamantyl, benzyl, phenyl, 4-hydroxyphenyl and the like.

Examples of the repeating unit (A1) include the following:

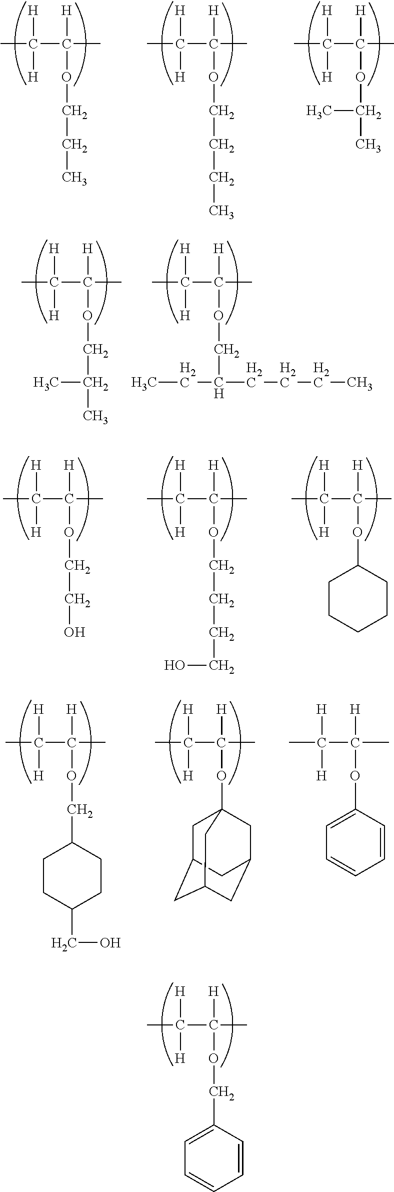

As to the repeating unit (A1), the carbon atom parameter represented by the formula (I) is preferably 2.0 to 5.0, more preferably 2.0 to 4.0, further preferably 2.0 to 3.5.

$$Carbon atom parameter = ( total number of atoms in the repeating unit ( A 1 ) ) / ( number of C in the repeating unit ( A 1 ) - number of O in the repeating unit ( A 1 ) ) \qquad ( I )$$

Also, as to the entire polymer (A), the formula (I)′ is preferably 2.0 to 5.0, more preferably 2.0 to 4.0, further preferably 2.0 to 3.5.

$$Carbon atom parameter = ( total number of atoms in the polymer ( A ) ) / ( number of C in the polymer ( A ) - number of O in the polymer ( A ) ) \qquad {( I )}^{′}$$

As to the repeating unit (A1), the ratio of the cyclic structure represented by the formula (II) is preferably 5 to 80%, more preferably 20 to 80%, in order to achieve more thickened film.

$$Cyclic structure ratio = ( sum of atomic weight of all atoms constituting the cyclic structure contained in the repeating unit ( A 1 ) ) / ( sum of atomic weight of all atoms constituting the repeating unit ( A 1 ) ) \times 100 \qquad ( II )$$

Also, as to the entire polymer (A), the formula (II)′ is preferably 5 to 80%, more preferably 20 to 80%.

$$Cyclic structure ratio = ( sum of atomic weights of all atoms constituting the cyclic structure contained in the polymer ( A ) ) / ( sum of atomic weights of all atoms constituting the polymer ( A ) ) \times 100 \qquad {( II )}^{′}$$

The polymer (A) can contain repeating units other than the repeating unit (A1) within a range that does not impair the scope of the present invention. The proportion occupied by the repeating unit (A1) is preferably 60 to 100%, more preferably 80 to 100%, further preferably 95 to 100%, based on the total of all repeating units constituting the polymer (A). In a further preferred embodiment, the polymer (A) essentially consists of the repeating unit (A1), and more preferably consists of the repeating unit (A1).

In the molecular weight distribution curve of the polymer (A) obtained by the gel permeation chromatography (GPC), the ratio of the amount having a molecular weight from 500 to 10,000 in terms of polystyrene to the total amount of the polymer (A) (sometimes referred to as “ratio of molecular weight from 500 to 10,000”) is preferably 60% or more, more preferably 70 to 100%, further preferably 80 to 100%.

The ratio of molecular weight from 500 to 10,000 can be determined in the following way.

First, in the molecular weight distribution curve of the thickening composition obtained by the GPC, the peak with the largest area ratio among the peaks in the molecular weight distribution curve is identified as the peak of the polymer (A).

Among the identified peaks of the polymer (A), an area in the range of 500 to 10,000 on the X axis of the molecular weight distribution curve (representing the molecular weight in logarithm) is determined, and the value obtained by dividing the above area by the area of the entire peaks of the polymer (A) and multiplying with 100 can be taken as the ratio of the amount of molecular weight from 500 to 10,000 in terms of polystyrene in the total polymer (A).

The mass average molecular weight of the polymer (A) is preferably 500 to 20,000, more preferably 500 to 8,000, further preferably 800 to 5,000, further more preferably 1,000 to 3,000. In the present invention, the mass average molecular weight (Mw) refers to the average mass molecular weight in terms of polystyrene measured using the GPC.

Although not to be bound by theory, it can be thought that in the repeating unit (A1), by being that the carbon atom parameter of the polymer (A) is 5.0 or less, the cyclic structure ratio is 5% or more, the ratio of molecular weight from 500 to 10,000 is 60% or more, or the mass average molecular weight is 500 or more, the effects of the present invention are exhibited more, and the following points are inferred.

First, it can be thought that when a thickening composition is applied on a resist layer and a thickening layer is formed by heating or the like, each polymer permeates at the parts where the thickening layer and resist layer are in contact (intermixing), and a mixed layer is formed. It can be thought that the formation of this mixed layer allows the resist pattern to be made thickened.

Further, it can be thought that since the amount of the thickening composition that permeates into the resist layer after application of the thickening composition on the resist layer is reduced, dissolution of the resist can be sufficiently suppressed.

Furthermore, it can be thought that a thickening layer with sufficient etching resistance can be formed.

Although not to be bound by theory, it can be thought that in the repeating unit (A1), by being that the polymer (A) has a carbon atom parameter of 2.0 or more, a cyclic structure ratio of 80% or less, or a mass average molecular weight of 10,000 or less, solubility of the exposed part of the thickening layer in the developer can be further improved. Further, it can be thought that solubility of the polymer (A) in the solvent (B) can be further improved.

The content of the polymer (A) is preferably 0.01 to 30 mass %, more preferably 0.5 to 20 mass %, further preferably 1 to 10mass %, based on the total mass of the thickening composition.

The thickening composition comprises the polymer (A), but can comprise any polymer other than the polymer (A). The content of the polymer other than the polymer (A) is preferably 0 to 20 mass %, more preferably 0 to 10 mass %, further preferably 0 to 5 mass %, further more preferably 0 mass % (embodiment that it is not contained), based on the total mass of the thickening composition.

### (B) Solvent

The solvent (B) is one for dissolving the polymer (A) and other components used as necessary.

The solvent (B) preferably comprises a solvent (B1) represented by the formula (b1):

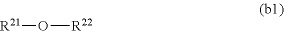

wherein R²¹ and R²² are each independently C₁₋₈ alkyl. Preferably, it is C₃₋₆ₛalkyl. More preferred are methyl, ethyl, n-propyl, isopropyl, n-butyl, t-butyl, n-pentyl, isopentyl, cyclopentyl or cyclohexyl. Further preferred are methyl, n-butyl, n-pentyl, isopropyl, cyclopentyl or cyclohexyl. Furthermore, preferred is n-butyl. These are linear, branched or cyclic, preferably linear or cyclic, more preferably linear.

R²¹ and R²² can be different or identical, but are preferably identical.

Examples of the solvent (B1) include dibutyl ether, dipentyl ether, diisopentyl ether, dicyclopentyl ether, dicyclohexyl ether and cyclopentyl methyl ether.

In one preferred embodiment, the solvent (B) preferably consists essentially only of the solvent (B1), and more preferably consists only of the solvent (B1).

In another preferred embodiment, the solvent (B) preferably comprises a solvent (B2) that is different from the solvent (B1), and more preferably consists only of the solvent (B1) and the solvent (B2).

Preferably, the solvent (B2) is cyclohexanone, cyclopentanone, propylene glycol monomethyl ether (PGME), propylene glycol monoethyl ether, propylene glycol monopropyl ether, propylene glycol monobutyl ether, propylene glycol dimethyl ether, propylene glycol diethyl ether, propylene glycol monomethyl ether acetate (PGMEA), propylene glycol monoethyl ether acetate, propylene glycol monopropyl ether acetate, y-butyrolactone, ethyl lactate, 2-propanol (IPA) or a combination of any of these. The solvent (B2) is preferably PGME, PGMEA or a combination of these. When the solvents contained in the solvent (B2) are two types, the mass ratio thereof is preferably 100:1 to 1:100, more preferably 50:1 to 1:50, further preferably 30:1 to 1:30.

The solvent (B2) can contain water. The water content is preferably 5 mass % or less, more preferably 1 mass % or less, further preferably 0.001 mass % or less, based on the solvent (B). It is also a preferred embodiment of the present invention that the solvent (B2) does not contain water (0.000 mass %).

Although not to be bound by theory, it can be thought that by dissolving the solid components (components other than the solvent (B)) while avoiding dissolving the underlying resist film, the solvent (B) of the composition according to the present invention can contribute to formation of the thickened pattern.

The content of the solvent (B) is preferably 70 to 99.99 mass %, more preferably 80 to 99.99 mass %, further preferably 95 to 99.99 mass %, further more preferably 95 to 99.90 mass %, based on the composition according to the present invention.

The content of the solvent (B1) is preferably 70 to 100 mass %, more preferably 80 to 100 mass %, further preferably 90 to 100 mass %, based on the solvent (B).

The content of the solvent (B2) is preferably 0 to 30 mass %, more preferably 0 to 20 mass %, further preferably 0.1 to 10 mass %, based on the solvent (B).

### (C) Surfactant

The thickening composition according to the present invention can further comprise a surfactant (C). The coatability can be improved by including the surfactant (C). Examples of the surfactant that can be used in the present invention include (I) anionic surfactants, (II) cationic surfactants, or (III) nonionic surfactants, and more particularly (I) alkyl sulfonate, alkyl benzene sulfonic acid and alkyl benzene sulfonate, (II) lauryl pyridinium chloride and lauryl methyl ammonium chloride and (III) polyoxyethylene octyl ether, polyoxyethylene lauryl ether, polyoxyethylene acetylenic glycol ether, fluorine-containing surfactants (for example, Fluorad (3M), Megafac (DIC), Surflon (AGC) and organic siloxane surfactants (for example, KF-53, KP341 (Shinetsu Chemical Industry)).

These surfactants can be used alone or in combination of two or more of these.

The content of the surfactant (C) is preferably 0 to 5 mass %, more preferably 0.001 to 2 mass %, further preferably 0.01 to 1 mass %, based on the total mass of the thickening composition. It is also one embodiment of the present invention that the surfactant (C) is not contained (0 mass %).

### (D) Additives

The thickening composition according to the present invention can further contain an additive (D) other than the above-mentioned components (A) to (C). The additive (D) is preferably a plasticizer, a crosslinking agent, an antibacterial agent, a germicide, an antiseptic, an antifungal agent, an acid, a base, an organic salt, or a mixture of at least any of these.

The content of the additive (D) is preferably 0 to 10 mass %, more preferably 0.001 to 5 mass %, further preferably 0.01 to 4 mass %, further more preferably 0.1 to 3 mass %, based on the total mass of the thickening composition. It is also a preferred embodiment of the present invention that the film thickening composition according to the present invention does not contain the additive (D) (0 mass %).

### Method for Manufacturing Thickened Resist Pattern

The method for manufacturing a thickened resist pattern according to the present invention comprises the following steps:
(1) applying a resist composition above a substrate to form a resist layer from the resist composition;
(2a) exposing the resist layer;
(2b) applying the thickening composition according to the present invention to the resist layer to form a thickening layer; and
(2c) developing the resist layer and the thickening layer.

Hereinafter, each step is explained using figures. Although describing for clarity, the steps (1), (2a), (2b) and (2c) are performed before the step (3). The numbers in parentheses indicating the steps mean the order. Provided that (2a), (2b) and (2c) can be placed in any order. The same applies hereafter.

### Step (1)

In the step (1), a resist composition is applied above the substrate to form a resist layer.

Examples of the substrate include a silicon/silicon dioxide coated substrate, a silicon nitride substrate, a silicon wafer substrate, a glass substrate, and an ITO substrate.

The resist composition is not particularly limited, but from the viewpoint of forming a fine resist pattern with high resolution, it is preferably a chemically amplified resist composition, and for example, a chemically amplified PHS-acrylate hybrid-based EUV resist composition is included. It is also a preferred embodiment that the resist composition comprises a photoacid generator. A suitable resist composition of the present invention is a positive-type chemically amplified resist composition.

As the resist composition of the present invention, it is also possible to use a negative-type resist composition. Known negative resist compositions and processes can be used.

The resist composition is applied above a substrate by an appropriate method. In the present invention, “above a substrate” includes a case where it is applied immediately above a substrate and a case where it is applied via another layer. For example, a resist underlayer film (for example, SOC (Spin On Carbon) and/or adhesion enhancing film) can be formed immediately on a substrate, and the resist composition can be applied immediately on the resist underlayer film. Preferably, the resist composition is applied immediately on the substrate. Further, in another preferred embodiment, the SOC is formed immediately on the substrate, the adhesion enhancing film is formed immediately on the SOC, and the resist composition is applied immediately on the adhesion enhancing film.

The application method is not particularly limited, but examples thereof include application by spin coating.

For the substrate on which the resist composition is applied, preferably by heating, a resist layer is formed. This heating is also called prebaking and is performed, for example, using a hot plate. The heating temperature is preferably 100 to 250° C.; more preferably 100 to 200° C.; further preferably 100 to 160° C. The temperature here is a heating surface temperature of the hot plate. The heating time is preferably 30 to 300 seconds; more preferably 30 to 120 seconds; further preferably 45 to 90 seconds. The heating is preferably performed in an air or nitrogen gas atmosphere; more preferably in an air atmosphere.

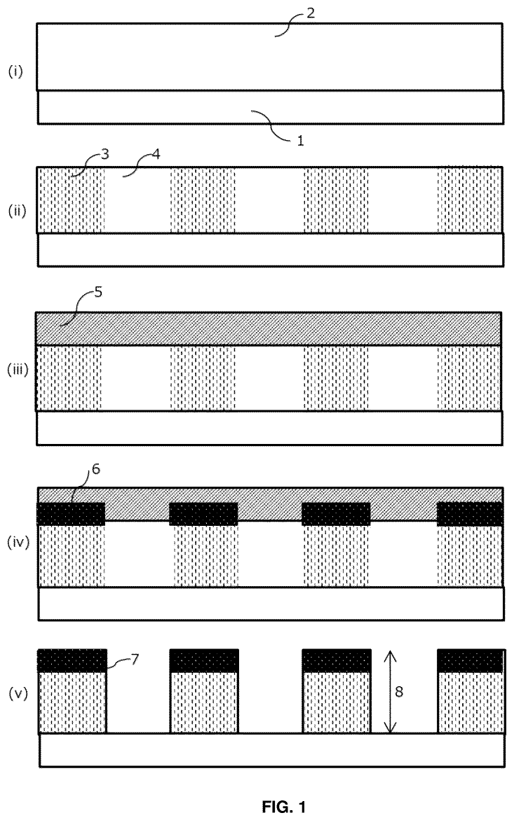

FIG. 1 (i) is a schematic illustration in which a resist layer 2 is formed on a substrate 1. The film thickness of the resist layer is selected depending on the intended purpose, but is preferably 10 to 100 nm; more preferably 10 to 40 nm; and further preferably 10 to 30 nm.

### Step (2a)

In the step (2a), the resist layer is exposed through a mask, if desired.

The wavelength of the radiation (light) used for exposure is not particularly limited, but it is preferable to expose with light having a wavelength of 13.5 to 248 nm. In particular, KrF excimer laser (wavelength: 248 nm), ArF excimer laser (wavelength: 193 nm), EUV (extreme ultraviolet, wavelength 13.5 nm), or the like can be used. EUV light is more preferred. These wavelengths are accepted in the range of ±1%.

After exposure, post exposure baking (PEB) can be performed, if necessary. The temperature for the PEB can be selected from the range of 70 to 150° C.; preferably 80 to 120° C. The heating time for the PEB can be selected from the range of 0.3 to 5 minutes; preferably 0.5 to 2 minutes.

FIG. 1 (ii) is a schematic illustration showing a state in which the resist layer 2 is exposed through a mask in the case using a typical positive-type chemically amplified resist composition. An acid is released from the photoacid generator to the exposed area 4, whereby the polymer is deprotected and alkali solubility thereof is increased. In the unexposed area 3, alkali solubility of the polymer does not change.

### Step (2b)

In the step (2b), a thickening composition comprising the polymer (A) and the solvent (B) is applied on the resist layer to form a thickening layer.

The application method is not particularly limited, but examples thereof include application by spin coating.

For the substrate on which the thickening composition is applied, preferably by heating or spin-drying (more preferably by heating), a thickening layer is formed. The heating is performed, for example using a hot plate. The heating temperature is preferably 45 to 150° C.; more preferably 90 to 130° C. The heating time is preferably 30 to 180 seconds; more preferably 45 to 90 seconds. The heating is preferably performed in an air or nitrogen gas atmosphere, more preferably in an air atmosphere. The heating in the step (2b) is also referred to as mixing bake.

FIG. 1 (iii) is a schematic illustration of a state in which the thickening layer 5 is formed on the resist layer 2.

In the step (2b), an insolubilized layer is preferably formed in a region in the vicinity where the thickening layer and the resist layer are in contact with each other. Although not to be bound by theory, it can be thought that each polymer permeates (intermixing) in the region where the thickening layer and the resist layer are in contact with each other to become a mixed layer. Whether the mixed layer is soluble or insoluble in the developer in the subsequent developing process depends on whether the underlying resist layer is soluble or insoluble in the developer. If the region of the underlying resist layer is insoluble in the developer, the mixed layer becomes an insolubilized layer. If the region of the underlying resist layer is soluble in the developer, the mixed layer also becomes soluble.

An instance of a positive-type resist layer is explained. Since the exposed area of the resist layer has become soluble in the developer, the resist layer (matrix component, preferably a polymer) that has permeated into the mixed layer in the same area is dissolved, and the mixed layer is also dissolved. Further, the exposed area of the resist layer under the mixed layer is also dissolved. On the other hand, the unexposed area of the resist layer has become insoluble in the developer (for example, it has not been deprotected). Therefore, the resist layer that permeates into the mixed layer in the same area is insoluble, and the mixed layer also does not dissolve. Further, the unexposed area of the resist layer under the mixed layer also does not dissolve.

FIG. 1 (iv) is a schematic illustration of a state in which an insolubilized layer 6 is formed. A mixed layer is also formed in the area that dissolves (exposed area, in the case of the positive type), but it is not shown in (iv) for convenience because it is dissolved and removed in the developing process.

In the step (2b), it is also preferable to perform rinsing after forming the thickening layer to remove the upper part of the thickening layer (thickening layer upper than the mixed layer). For the rinsing, one having the same composition as the solvent (B) of the thickening composition can be used. The rinsing in the present invention is different from the development to be described later. That is, the rinsing is not for dissolving the soluble area of the resist layer to form a resist pattern.

### Step (2c)

In the step (2c), the resist layer, or the resist layer and the thickening layer are developed.

Examples of the application method of the developer include a paddle method, a dip method and a spray method. The temperature of the developer is preferably 5 to 50° C.; more preferably 25 to 40° C., and the developing time is preferably 15 to 120 seconds; more preferably 30 to 60 seconds. After applying the developer, the developer is removed. The resist pattern after development can be also subjected to rinsing treatment. The rinsing treatment can preferably be carried out with water (DIW).

The developer is preferably an alkaline aqueous solution or an organic solvent; more preferably an alkaline aqueous solution. Examples of the alkaline aqueous solution include aqueous solutions containing inorganic alkalis such as sodium hydroxide, potassium hydroxide, sodium carbonate and sodium silicate, organic amines such as ammonia, ethylamine, propylamine, diethylamine, diethylaminoethanol and triethylamine, and a quaternary amine such as tetramethylammonium hydroxide (TMAH) or the like; more preferably a TMAH aqueous solution; further preferably a 2.38 mass % TMAH aqueous solution.

The above-mentioned surfactant can be further added to the developer. The order of (2a), (2b) and (2c) can be in any order. Since it is not necessary to expose while passing through the thickening layer, the process of performing the step (2b) after (2a) is more preferable. A process in which the step (2a) is performed after (2b) is also possible, and in this case, it is preferable to perform the exposure after controlling the influence of its transmission through the thickening layer. Since only one development process is required, it is preferable to perform (2c) after (2a) and (2b). In a preferred embodiment of the present invention, the steps (2a), (2b) and (2c) are performed in this order.

FIG. 1 (v) shows a state in which the developer is applied to the resist layer and the thickening layer, the developer is removed, and the thickened resist pattern 7 is formed.

When (height of the thickened resist pattern)−(height of the resist pattern formed in the same manner except that the thickening composition is not applied) is taken as the film-thickened amount, the film-thickened amount is preferably 2 to 20 nm; more preferably 2 to 15 nm; further preferably 5 to 10 nm; furthermore preferably 5.5 to 8 nm. Although not to be bound by theory, in the high-defined lithography techniques such as EUV exposure, it is general that thickness of the resist film is thin. However, it can be thought that by thickening the resist film according to the present invention, when used in a later step, for example, as an etching mask, the durability as a mask can be ensured.

### Method for Manufacturing Processed Substrate and Device

The method for manufacturing a processed substrate according to the present invention comprises the following steps: forming the above-described thickened resist pattern; and (3) processing using the thickened resist pattern as a mask.

### Step (3)

In the step (3), processing is performed using the thickened resist pattern as a mask.

The thickened resist pattern is preferably used for processing a resist underlayer film or a substrate (more preferably a substrate). In particular, using the resist pattern as a mask, various substrates that becomes an underlaying material can be processed using a dry etching method, a wet etching method, an ion implantation method, a metal plating method, or the like. Since the resist pattern is thickened, it can function as a mask even under severe conditions, and therefore, it is preferably used for processing by a dry etching method.

When processing the resist underlayer film using the thickened resist pattern, the processing can be performed step by step. For example, the resist pattern can be used to process the adhesion enhancing film and the SOC, and the SOC pattern can be also used to process the substrate. As the adhesion enhancing film, for example, SiARC (Si Anti-Reflective Coating) can be used.

The method for manufacturing a device according to the present invention comprises the above method, and optionally further comprises a step of forming a wiring on the processed substrate. Known methods can be applied to these processings. Thereafter, if necessary, the substrate is cut into chips, connected to a lead frame, and packaged with resin. In the present invention, this packaged one is referred to as a device. Examples of the device include a semiconductor device, a liquid crystal display device, an organic EL display device, a plasma display device, and a solar cell device. The device is preferably a semiconductor device.

The present invention relates to the use of a composition comprising a polymer (A) comprising a repeating unit (a1) represented by the formula (a1), and a solvent (B) for forming a film on a resist layer. Preferred embodiments of the polymer (A) and the solvent (B) are as described above. The composition comprising the polymer (A) and the solvent (B) is preferably a thickening composition, and preferred embodiments are as described above.

### EXAMPLE

The present invention is described below with reference to various examples. The embodiments of the present invention are not limited to these examples.

### Synthesis of Polymer (A)

### (1) Synthesis of Poly(Cyclohexyl Vinyl Ether)

A 100 mL three-necked flask is dried for 10 minutes using a heat gun under nitrogen atmosphere. Then, n-butylammonium bromide and dichloromethane are added to the three-necked flask to prepare 32 mL of a 5.25 mmol/L solution. Then, 4 mL of a dichloromethane solution of 40 mmol/L trifluoromethanesulfonic acid is added to the three-necked flask using a dry syringe. The solution is made to be-40° C., 4 mL of cyclohexyl vinyl ether is added, and the mixture is allowed to react for 27 hours. Thereafter, a mixed solution of 5 mL of 0.1 mass % ammonia aqueous solution and 5 mL of ethanol is added, and the reaction is stopped. The mixture is washed three times with 30 ml of water, 10 g of magnesium sulfate is added and allowed to stir for 5 minutes, then the solid is filtered and the solvent is removed from the resulting mixture under reduced pressure. It is then dried using vacuum under reduced pressure for more than 3 hours at room temperature to obtain poly (cyclohexyl vinyl ether) (Mw: 1,800, PDI (Poly Dispersity Index) =1.9) with a yield of 82%.

### (2) Synthesis of Poly(Isobutyl Vinyl Ether)

Synthesis is performed by the same method as in Synthesis (1) except that cyclohexyl vinyl ether is changed to isobutyl vinyl ether.

Poly(isobutyl vinyl ether) at this time has a Mw of 1,960, a PDI of 2.1 and is obtained with a yield of 76%.

### (3) Synthesis of Poly(Isopropyl Vinyl Ether)

Synthesis is performed by the same method as in Synthesis (1) except that cyclohexyl vinyl ether is changed to isopropyl vinyl ether.

Poly (isopropyl vinyl ether) at this time has a Mw of 2,040, a PDI of 2.0 and is obtained with a yield of 73%.

### Preparation of Compositions of Examples 1 to 3 and Reference Example 1

Polymer (A) listed in Table 1 is dissolved in solvent (B) which is dibutyl ether. The content of the polymer (A) is 1.0 mass % based on the total mass of the composition. The resulting solution is stirred at room temperature for 60 minutes. After visually confirming that the solute is completely dissolved, this solution is filtered through a 0.2 μm fluororesin filter to obtain each composition of Examples 1 to 3.

In Reference Example 1, cyclohexyl vinyl ether (molecular weight: 126.2, carbon atom parameter: 3.3) that is a monomer is used in place of the polymer (A) and preparation is performed in the same manner as above, thereby obtaining the composition of Reference Example 1.

TABLE 1
Table 1

| | | Ratio of | | | | |
|---|---|---|---|---|---|---|
| | | molecular | Film- | Film | | |
| | | weight | thickened | thickness | | Etching |
| | Polymer (A) | 500~10,000 | amount | variation | LWR | resistance |
| Example 1 | P1 | 98% | 7 nm | A | A | A |
| Example 2 | P2 | 84% | 6 nm | A | A | A |
| Example 3 | P3 | 79% | 6 nm | A | A | A |
| Reference | M1 | — | 5 nm | B | B | B |
| Example 1 | | | | | | |

In the table,
P1: Poly (cyclohexyl vinyl ether), Mw: 1,800, carbon atom parameter: 3.3, cyclic structure ratio: 65%,

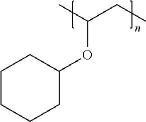

P2: Poly (isobutyl vinyl ether), Mw: 1,960, carbon atom parameter: 3.8,

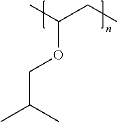

P3: Poly (isopropyl vinyl ether), Mw: 2,040, carbon atom parameter: 4.0,

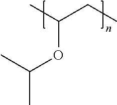

M1: cyclohexyl vinyl ether, molecular weight: 126.2, carbon atom parameter: 3.3.

### Measurement of Mass Average Molecular Weight (Mw)

The mass average molecular weight (Mw) of each composition of Examples 1 to 3 and Reference Example 1 is measured by using GPC columns (Tosoh Corporation, two “G2000HXL” and one “G3000HXL”) under the analysis conditions of flow rate: 1.0 ml/min, elution solvent: tetrahydrofuran (Kishida Kagaku) and column temperature: 40° C., by the gel permeation chromatography (detector: differential refractometer) in terms of monodisperse polystyrene as a standard. The sample to be analyzed is prepared by dissolving the polymer in tetrahydrofuran to obtain a 0.5 wt. % solution, and then filtering the solution through a PTFE filter with a 0.2 μm pore size, thereby analyzing.

### Calculation of Ratio of Molecular Weight from 500 to 10,000

For each composition of Examples 1 to 3 and Reference Example 1, a molecular weight distribution curve is obtained by measuring using the gel permeation chromatography in the same manner as above. Among the peaks that the molecular weight distribution curve has, a peak with the largest area ratio is taken as the peak of the polymer (A).

Among the peaks of the polymer (A), an area in the range of 500 to 10,000 on the X axis of the molecular weight distribution curve (representing the molecular weight in logarithm) is determined, and the value obtained by dividing the above area by the area of the entire peaks of the polymer (A) and multiplying with 100 is taken as the ratio of the amount of molecular weight from 500 to 10,000 in terms of polystyrene in the total polymer (A). The results obtained are shown in Table 1.

### Evaluation of Film Thickness Variation

A silicon substrate is treated with HMDS (hexamethyldisilazane) at 90° C. for 30 seconds. A PHS-acrylate hybrid-based chemically amplified resist composition (positive type) for EUV is applied on the HMDS-treated substrate by spin coating and heated on a hot plate at 110° C. for 60 seconds to form a resist layer having a film thickness of 35 nm. The composition of Example 1 is poured, thereby covering the resist layer with the composition of Example 1, and that state is left for 60 seconds. Thereafter, the substrate is rotated at high speed and dried. The film thickness at this time is measured using an ellipsometer M-2000 (J.A. Woollam). One obtained by subtracting the film thickness (35 nm) of the resist layer from the film thickness at this time is defined as the of film-thickened amount, and the obtained results are shown in Table 1.

Evaluation of film thickness variation is done according to the following criteria. The results obtained are shown in Table 1.

$$A : 5. nm < film - thickened amount \leq 10. nm$$

$$B : film - thickened amount \leq 5. nm$$

For each composition of Examples 2 and 3 and Reference Example 1, evaluation is done in the same manner.

### LWR Evaluation

A silicon substrate is treated with HMDS at 90° C. for 30 seconds. A PHS-acrylate hybrid-based chemically amplified resist composition (positive type) for EUV is applied on the HMDS-treated substrate by spin coating and heated on a hot plate at 110° C. for 60 seconds to form a resist layer having a film thickness of 35 nm. The resist layer is exposed using an EUV stepper (NXE: 3300B, ASML) through a mask with a size of 18 nm (line: space=1:1) while changing the exposure amount. Thereafter, post-exposure baking (PEB) is performed at 100°° C. for 60 seconds. Thereafter, the composition of Example 1 is applied onto the resist layer by spin coating and heated at 90° C. for 60 seconds to form a thickening layer. After that, puddle development is performed for 30 seconds using a 2.38 mass % TMAH aqueous solution as a developer, water is started to be dripped in the state that the developer is being puddled on the substrate, and the water is continued to be dripped while the substrate is being rotated, thereby replacing the developer with water. Thereafter, the substrate is rotated at high speed to dry the thickened resist pattern of Example 1. The obtained thickened resist pattern is observed using a SEM device CG6300 (Hitachi High Technologies), and the line width and LWR (Line Width Roughness) value are measured. ((LWR value/line width)×100) is calculated, the value is taken as X, the evaluation thereof is performed according to the following criteria, and the obtained results are shown in Table 1.

$$A : X \leq 20$$

$$B : X > 20$$

For each composition of Examples 2 and 3 and Reference Example 1, evaluation is done in the same manner.

### Evaluation of Etching Resistance

A silicon substrate is treated with HMDS at 90° C. for 30 seconds. A PHS-acrylate hybrid-based chemically amplified resist composition (positive type) for EUV is applied on the HMDS-treated substrate by spin coating and heated on a hot plate at 110° C. for 60 seconds to form a resist layer having a film thickness of 35 nm. The composition of Example 1 is applied onto the resist layer by spin coating and heated at 90° C. for 60 seconds to form a thickening layer. The obtained substrate is placed in a dry etching apparatus, and plasma etching is performed for 15 seconds at a substrate temperature of 23° C. using a mixed gas of CF₄ (5 mL/min), O₂ (10 mL/min) and Ar (500 mL/min). Thereafter, the remaining film amount of the resist film is measured using an ellipsometer M-2000 (J.A. Woollam). The remaining film amount at this time is taken as Y₁. The larger the remaining film amount, the better the plasma etching resistance.

As a comparison object, a resist layer with a film thickness of 35 nm is also etched in the same manner as above, and the remaining film amount is measured. The remaining film amount at this time is taken as Y₂.

Y=Y₁/Y2×100 is calculated and evaluation thereof is done according to the following criteria, and the obtained results are shown in Table 1.

$$A : 110 < Y$$

$$B : 100 < Y \leq 110$$

For each composition of Examples 2 and 3 and Reference Example 1, evaluation is done in the same manner.

### EXPLANATION OF SYMBOLS

1. substrate
2. resist layer
3. unexposed area
4. exposed area
5. thickening layer
6. insolubilized layer
7. thickened resist pattern
8. height of thickened resist pattern

What is claimed is:

1. A thickening composition comprising:
a polymer (A) comprising a repeating unit (A1) represented by the formula (a1) and a solvent (B): 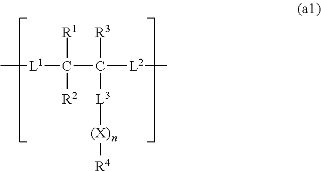
wherein
L¹, L² and L³ are each independently a single bond, C₁₋₁₀ linear alkylene, C₃₋₁₀ branched alkylene or C₃₋₁₀ cyclic alkylene;
R¹, R² and R³ are each independently H, C₁₋₁₀ linear alkyl, C₃₋₁₀ branched alkyl, C₃₋₁₀ cyclic alkyl, C₆₋₁₅ aryl or C₆₋₁₅ aralkyl;
R⁴ is C₁₋₁₅ linear alkyl, C₃₋₁₅ branched alkyl, C₃₋₁₅ cyclic alkyl, C₆₋₁₅ aryl, C₆₋₁₅ aralkyl or a combination of any of these;
wherein at least one of hydrogen atoms in R⁴ can be replaced with C₁₋₅ linear alkyl—COOH or —OH;
wherein at least one of non-adjacent methylene (—CH₂—) in L¹, L², L³, R¹, R², R³ and R⁴ can be replaced with —O—, —S—,—CO—, —CO—O—, —O—CO—, —O—CO—O—, -CR⁵⁼CR⁶- or —C≡C—;
R⁵ and R⁶ are each independently H or C₁₋₆ linear alkyl;
X is O or S; and
n is 0 or 1.

2. The thickening composition according to claim 1, wherein R⁴ is represented by the formula (a2): 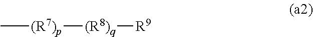
wherein
R⁷ is C₁₋₁₅ linear alkylene, C₃₋₁₅ branched alkylene, C₃₋₁₅ cyclic alkylene or phenylene;
R⁸ is C₁₋₁₅ linear alkylene, C₃₋₁₅ branched alkylene, C₃₋₁₅ cyclic alkylene or phenylene;
R⁹ is C₁₋₁₅ linear alkyl, C₃₋₁₅ branched alkyl, C₃₋₁₅ cyclic alkyl, phenyl or benzyl;
wherein at least one of hydrogen atoms in any of R⁷, R⁸ or R⁹ can be replaced with C₁₋₅ linear alkyl, —COOH or —OH; and
p and q are each independently 0 or 1.

3. The thickening composition according to claim 1, wherein the polymer (A) has a mass average molecular weight of 500 to 20,000.

4. The thickening composition according to claim 1, wherein an amount having a molecular weight in terms of polystyrene of 500 to 10,000 is 60% or more of the total amount of the polymer (A) in the molecular weight distribution curve obtained by gel permeation chromatography of the polymer (A).

5. The thickening composition according to claim 1, wherein a carbon atom parameter represented by the formula (I) is 2.0 to 5.0:
$$Carbon atom parameter = ( total number of atoms in the repeating unit ( A 1 ) ) / ( number of C in the repeating unit ( A 1 ) - number of O in the repeating unit ( A 1 ) ) . \qquad ( I )$$

6. The thickening composition according to claim 1, wherein a cyclic structure ratio represented by the formula (II) is 5 to 80%:
$$cyclic structure ratio = ( sum of atomic weights of all atoms constituting the cyclic structure included in the repeating unit ( A 1 ) ) / ( sum of atomic weights of all atoms constituting the repeating unit ( A 1 ) ) \times 100 . \qquad ( II )$$

7. The thickening composition according to claim 1, wherein L¹, L² and L³ are single bonds.

8. The thickening composition according to claim 1, wherein R¹, R² and R³ are H.

9. The thickening composition according to claim 1, wherein the content of the polymer (A) is 0.01 to 30 mass % based on the total mass of the thickening composition.

10. The thickening composition according to claim 1, wherein the solvent (B) comprises a solvent (B1) represented by the formula (b1): 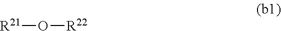
wherein
R²¹ and R²² are each independently linear, branched or cyclic C₁₋₈ alkyl,
optionally, the solvent (B) is 70 to 99.99 mass % based on the thickening composition; or
optionally, the solvent (B1) is 70 to 100 mass % based on the solvent (B).

11. A method for manufacturing a thickened resist pattern comprising the following steps:
(1) applying a resist composition above a substrate to form a resist layer from the resist composition (preferably by heating);
(2a) exposing the resist layer (preferably with EUV light);
(2b) applying the thickening composition according to one or more of claims 1 to 10 to the resist layer to form a thickening layer (preferably by heating or spin drying); and
(2c) developing the resist layer and the thickening layer (preferably developing with an alkaline aqueous solution or an organic solvent; more preferably developing with an alkaline aqueous solution).

12. The method according to claim 11, further comprising removing the upper part of the thickening layer by rinsing after forming the thickening layer in the step (2b).

13. The method according to claim 11, wherein the resist composition is a chemically amplified resist composition.

14. The method according to claim 11, wherein the resist composition further comprises a photoacid generator.

15. A method for manufacturing a processed substrate comprising the following steps:
forming a thickened resist pattern according to claims 11; and
(3) processing using the thickened resist pattern as a mask.

16. A method for manufacturing a device comprising the method according to claim 15:
optionally further comprising a step of forming a wiring on the processed substrate; and
optionally the device is a semiconductor device.
